(19) United States
(12) Patent Application Publication
(10) Pub. No.: US 2018/0034437 A1
(43) Pub. Date: Feb. 1, 2018

(54) DIFFERENTIAL TRANSMISSION LINE WITH COMMON MODE SUPPRESSION

(71) Applicant: Keysight Technologies, Inc., Minneapolis, MN (US)

(72) Inventors: Todd Steven Marshall, Los Gatos, CA (US); Dietrich W. Vook, Santa Clara, CA (US); Douglas Baney, Santa Clara, CA (US)

(21) Appl. No.: 15/223,910

(22) Filed: Jul. 29, 2016

(51) Int. Cl. H03H 7/42; H01P 3/08

(52) U.S. Cl. CPC H03H 7/427; H01P 3/088

(57) ABSTRACT

A differential transmission line includes a sheath, a first conductive structure, a second conductive structure, and a resistive layer. The first conductive structure is disposed along the differential transmission line and within the sheath, and contributes to formation of a three-dimensional electromagnetic field. The second conductive structure is disposed along the differential transmission line and within the sheath, and contributes to formation of the three-dimensional electromagnetic field. The resistive layer is aligned to be substantially perpendicular to an electric field component of a first mode of the three-dimensional electromagnetic field, and to provide absorption of an electric field component of a second mode of the three-dimensional electromagnetic field.

### BACKGROUND

### 1. Field of the Disclosure

The present disclosure relates to the field of differential electromagnetic transmissions. More particularly, the present disclosure relates to a differential electromagnetic transmission line with a resistive layer.

### 2. Background Information

In modern electronics, differential signals are often used to improve signal fidelity (signal to noise ratio). Differential signaling is used in a variety of settings, including:
high speed digital circuits
analog/radio frequency circuits
high speed computation and communications equipment
high voltage circuits

For computation and communications equipment, differential signaling (e.g., using a serializer/deserializer) is used to address a clock skew issue. In analog and radio frequency equipment, differential signaling reduces sensitivity to electromagnetic interference. For high voltage circuits, differential signaling can be used because both transmission mechanisms can be electrically floated, and control signals or analog signals can be provided independent of the DC offset voltage.

Differential signaling has costs too, and does not work perfectly in practice. For example, a single mode of signal propagation is typically desirable for electromagnetic signals, as multi-mode signal propagation may result in non-idealities due to coupling (interference) between signal components of the different modes. The desirable single mode may be referred to as the differential mode, an odd mode, a first mode and so on, and undesirable modes may be referred to as a common mode, an even mode, a higher order mode, a second mode, a third mode, a fourth mode and so on.

Selective filters have been used to suppress the undesirable (common, even, higher order, second/third/fourth) mode signals on differential transmission assemblies. The differential transmission assemblies are loaded with stopband filters for the undesirable mode signals and all-pass filters for the desirable mode signals.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Whenever applicable and practical, like reference numerals refer to like elements.

FIG. 1 shows an exemplary interior cross section of a differential transmission line with common mode suppression, according to an aspect of the present disclosure;

FIG. 2 shows an exemplary interior cross section of another differential transmission line with common mode suppression, according to an aspect of the present disclosure;

FIGS. 3A-3C show exemplary interior cross sections for another differential transmission line in an assembly progression, according to an aspect of the present disclosure;

FIG. 4 shows an exemplary interior cross section of another differential transmission line with common mode suppression, according to an aspect of the present disclosure;

FIGS. 5A-5B show exemplary interior cross sections of additional differential transmission lines with common mode suppression, according to an aspect of the present disclosure;

FIG. 6 shows an exemplary interior profile of a differential transmission line with common mode suppression, according to an aspect of the present disclosure;

FIG. 7 shows an exemplary interior cross section of another differential transmission line with common mode suppression, according to an aspect of the present disclosure;

FIG. 8 shows an exemplary interior cross section of another differential transmission line with common mode suppression, according to an aspect of the present disclosure;

FIG. 9 shows a chart of 100 Ohm odd-mode impedance between two center conductive structures at frequencies up to 50 Gigahertz for a differential transmission line without common mode suppression, according to an aspect of the present disclosure

FIG. 10 is a plot of Nepers/Meter versus frequency for the real part of the propagation constant for the first mode of the same differential transmission line without common mode suppression as in FIG. 9, according to an aspect of the present disclosure;

FIG. 11 is a plot of Nepers/Meter versus frequency for the real part of the propagation constant for the second mode of the same differential transmission line without common mode suppression as in FIG. 9, according to an aspect of the present disclosure;

FIG. 12 is a plot of Nepers/Meter versus frequency for the real part of the propagation constant for the first higher order mode of the same differential transmission line without common mode suppression as in FIG. 9, according to an aspect of the present disclosure;

FIG. 13 is a plot of Nepers/Meter versus frequency for the real part of the propagation constant for the second higher order mode of the same differential transmission line without common mode suppression as in FIG. 9, according to an aspect of the present disclosure;

FIG. 14 is a plot of Nepers/Meter versus frequency for the real part of the propagation constant for the second mode (common) of another (modified) differential transmission line with common mode suppression, according to an aspect of the present disclosure;

FIG. 15 is a plot of Nepers/Meter versus frequency for the real part of the propagation constant for the first higher order mode of the same modified differential transmission line with common mode suppression as in FIG. 14, according to an aspect of the present disclosure;

FIG. 16 is a plot of Nepers/Meter versus frequency for the real part of the propagation constant for the second higher order mode of the same modified differential transmission line with common mode suppression as in FIG. 14, according to an aspect of the present disclosure;

FIG. 17 shows a cross-sectional view of a differential transmission line with field lines for the odd mode, according to an aspect of the present disclosure;

FIG. 18 shows a cross-sectional view of the same differential transmission line as in FIG. 17 but with field lines for the even mode, according to an aspect of the present disclosure;

FIG. 19 shows a cross-sectional view of the same differential transmission line as in FIG. 17 but with field lines for the first higher order mode, according to an aspect of the present disclosure; and

FIG. 20 shows a cross-sectional view of the same differential transmission line as in FIG. 17 but with field lines for the second higher order mode, according to an aspect of the present disclosure.

### DETAILED DESCRIPTION

In the following detailed description, for purposes of explanation and not limitation, representative embodiments disclosing specific details are set forth in order to provide a thorough understanding of the present teachings. Descriptions of known systems, devices, materials, methods of operation and methods of manufacture may be omitted so as to avoid obscuring the description of the example embodiments. Nonetheless, systems, devices, materials and methods that are within the purview of one of ordinary skill in the art may be used in accordance with the representative embodiments.

It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the inventive concept.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

It will be understood that when an element or component is referred to as being “connected to”, “coupled to”, or “adjacent to” another element or component, it can be directly connected or coupled to the other element or component, or intervening elements or components may be present. In contrast, when an element is referred to as being “directly connected to” or “directly coupled to” another element or component, there are no intervening elements or components present.

In view of the foregoing, the present disclosure, through one or more of its various aspects, embodiments and/or specific features or sub-components, is thus intended to bring out one or more of the advantages as specifically noted below. For purposes of explanation and not limitation, example embodiments disclosing specific details are set forth in order to provide a thorough understanding of an embodiment according to the present teachings. However, other embodiments consistent with the present disclosure that depart from specific details disclosed herein remain within the scope of the appended claims. Moreover, descriptions of well-known apparatuses and methods may be omitted so as to not obscure the description of the example embodiments. Such methods and apparatuses are within the scope of the present disclosure.

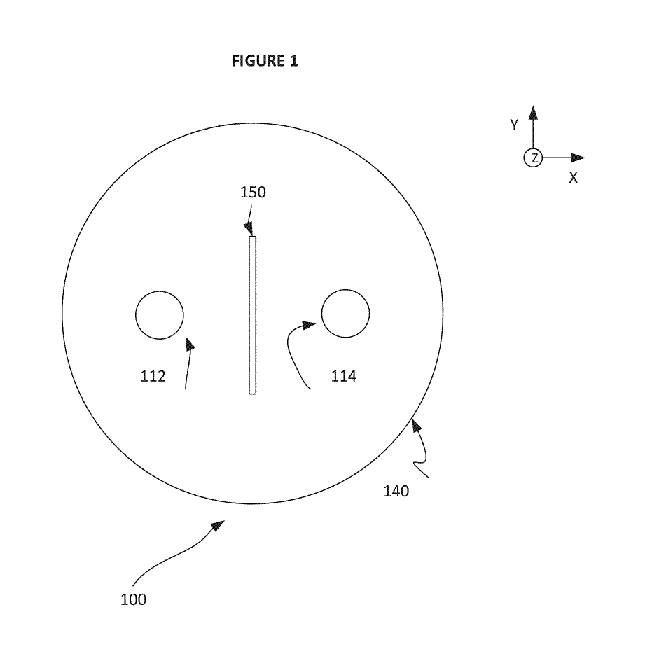

FIG. 1 shows an exemplary interior cross section of a differential transmission line 100 with common mode suppression, according to an aspect of the present disclosure. A “differential mode” as used herein may also be referenced as an odd mode, and the signal components provided by the differential mode are referred to herein as “differential mode signals”. A “common mode” as used herein may also be referenced as, for example, an even mode, and the signal components provided by the common mode are referred to herein as “common mode signals”. In transmission along a differential transmission line 100, the differential mode signal is a signal that appears with opposite polarity on two conductive structures 112, 114, and the voltage difference between the signal components is carried by the two conductive structures 112, 114. The common mode signal is a signal that appears equally on the two conductive structures 112, 114, and has the absence of any difference in amplitude or polarity between the signal components carried by the two conductive structures 112, 114.

In the descriptions provided herein, the differential signals are the signals intended in a differential transmission line 100. For the purposes of the present disclosure, common mode signals are essentially undesirable noise to be filtered or removed. This may not be true in other circumstances outside of the present disclosure, as others may wish to retain the common mode signals in certain circumstances beyond the scope of the present disclosure.

The view shown in FIG. 1 is a cross sectional outline of the differential transmission line 100. In FIG. 1, two metal conductive structures 112, 114 are completely separated by a space as shown. Each conductive structure 112, 114 is a solid three-dimensional object which carries a signal (i.e., is an electrical conductor), and combined the conductive structures 112, 114 are used to provide a differential signal. Such solid objects may, of course, be hollow conductors insofar as spaces in the conductive structures 112, 114 are tolerable. The conductive structures 112, 114 are forms of metal objects known to carry electronic signals with characteristic impedance defined by the cross-section geometry. In practice, the characteristic impedance is engineered to be either uniform or non-uniform along the longitudinal propagation direction by having arbitrary discrete or continuous variations of the structures 112, 114 cross-sections. Cross sections of the conductive structures 112, 114 may have substantially the same dimension and shape from front face to rear face when keeping the characteristic impedance uniform. Known design approximations, such as the Wentzel-Kramers-Brillouin (WKB) approximation, are a standard practice to design non-uniform transmission lines, including the differential electromagnetic transmission line with a resistive layer. Cross sections of the conductive structures 112, 114 may have substantially different dimension and shape from front face to rear face when the characteristic impedance is non-uniform. The conductive structures 112, 114 may also have additional characteristics, such as by having two end faces on opposite sides, i.e., a single rear face (not shown) on the opposite side of the single front face shown in FIG. 1, at least when the conductive structures 112, 114 are laid out in line. In practice, such conductive structures 112, 114 may be bent in one or more places, such that the two end faces are not parallel.

The conductive structures 112, 114 may also have additional characteristics, such as having two end faces on opposite sides, i.e., including a single rear face (not shown) on the opposite side of the single front face shown in FIG. 1, at least when the conductive structures 112, 114 are laid out in line. In practice, of course, such conductive structures 112, 114 may be bent in one or more places, such that the two end faces are not parallel.

In microwaves transmission lines, interior conductors may have rounded edges which avoid current crowding that might otherwise occur at sharp vertices. Additionally, common microwave components are not uniform in the direction of propagation and, as such, conductive structures 112, 114 and others described herein may not be uniform in the propagation direction.

The conductive structures 112, 114 are positive (+) and negative (−) conductors of a differential transmission line 100 in FIG. 1. The signal of interest is carried by differences of voltage and current between the two conductive structures 112, 114. In addition to the intended and desirable differential signal of the differential mode, the differential transmission line 100 is also accompanied by at least an undesirable common (second, even) mode signal, as well as possibly additional undesirable higher order mode signals. Higher order modes beyond the even mode (common) described herein are referred to herein as, for example, the first higher order mode and the second higher order mode. The intended signal provided by the two conductive structures 112, 114 is a differential signal provided by the differential mode. Conductive structures 112, 114 and others described herein may be any suitable electrical conductor and may use materials such as silver, copper, gold, aluminum or other metal, metal alloy, or non-metal electrical conductors.

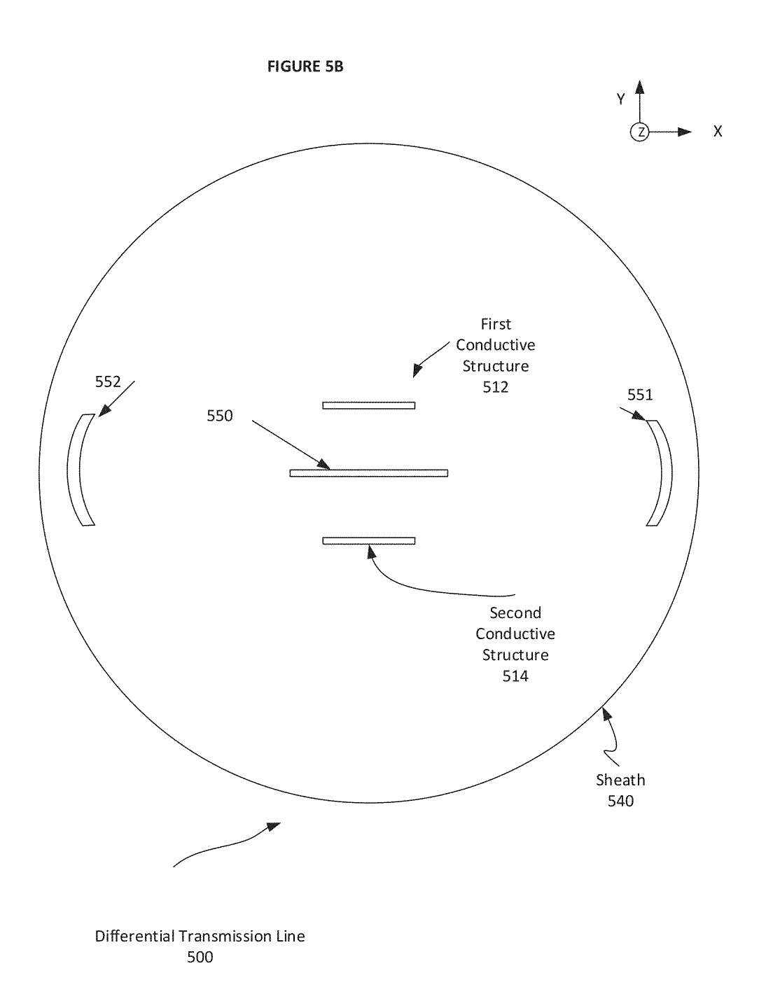

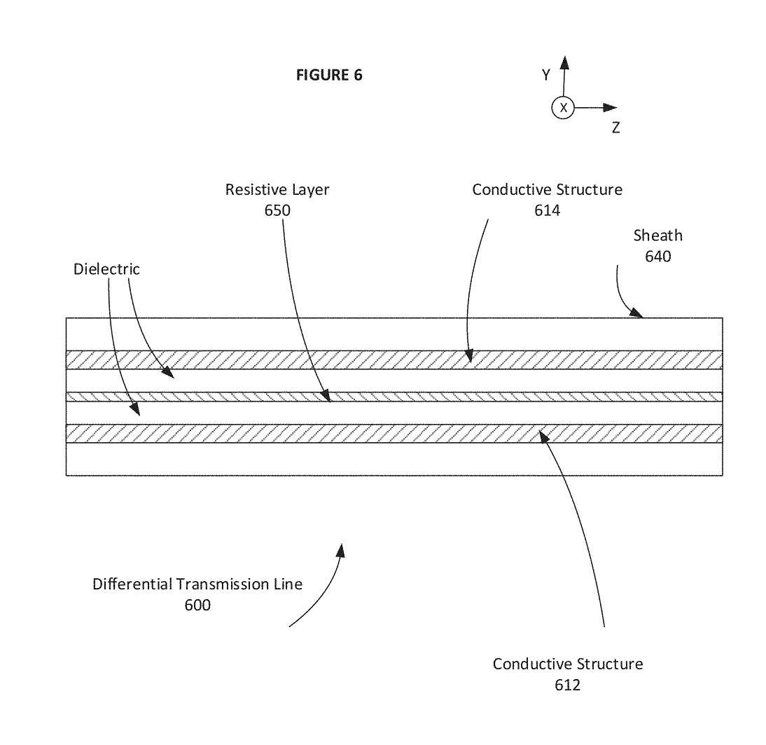

The differential signal line 100 shown in FIG. 1 also includes an outer sheath 140, which is an outer shield for the components carried in the differential signal line 100. The outer sheath 140 can include a protective plastic coating or other suitable protective material, and is preferably a conductive sleeve, though the outer sheath 140 may alternatively be an insulator. The differential signal line 100 may also include dielectric components within the outer sheath 140 in areas not otherwise occupied by components described herein. Such dielectric components may include one or more dielectric layers and are indicated in, for example, the profile view shown in FIG. 6 of the differential transmission lines of FIGS. 5A and 5B.

In FIG. 1, the direction of transmission for the differential transmission line 100 is the direction coming out of the page. The signal is carried by the two conductive structures 112, 114. In FIG. 1, the conductive structures 112, 114 appear identical and symmetric in size, shape and orientation on the page. Symmetry may be useful for a variety of reasons including simplicity of design; however, symmetry between the two conductive structures 112, 114 is not an absolute requirement, and some other electrical conductors described herein are not symmetric.

In differential signaling, one of the conductive structures 112, 114 carries a positive signal, and the other of the conductive structures 112, 114 carries a negative signal that is equal to the positive signal but with the opposite polarity. The signal of interest in FIG. 1 is carried by differences of voltage and current between the conductive structures 112, 114. The conductive structures 112, 114 are driven differentially, and each contributes to formation of a three-dimensional electromagnetic field.

In the view of FIG. 1, a single front face of each conductive structure 112, 114 is shown. The differential transmission line 100 may be, for example, a cable, and the conductive structures 112, 114 may be wires.

Examples of circuits and circuity that use differential signals and include differential transmission lines 100 as shown in FIG. 1 include:
high speed digital circuits
analog/radio frequency circuits
high speed computation and communications equipment

That is, differential transmission lines 100 can be used within equipment such as computation and communications equipment, as well as to link equipment such as computation and communications equipment. As explained below, due to the addition of resistive layer 150, differential transmission lines such as differential transmission line 100 can also be used for communications over longer distances and with wider bandwidths than comparable differential transmission assemblies known previously.

In FIG. 1, the differential transmission line 100 is grounded by the outer sheath 140. As explained herein, in differential signaling, common mode signals and higher order signals within the outer sheath 140 and resulting from signals between the two conductive structures 112, 114 are unwanted.

Remaining parts of a substrate that includes the outer sheath 140 may be a dielectric and may include materials such as, but not limited to, glass fiber material, plastics such as polytetrafluoroethylene (PTFE), low-k dielectric material with a reduced loss tangent (e.g., 10⁻²), ceramic materials, liquid crystal polymer (LCP), or any other suitable dielectric material, including air, and combinations thereof

In FIG. 1, a resistive layer 150 is placed between the conductive structures 112, 114 within the outer sheath 140. The resistive layer 150 is applied to attenuate common mode signals in the differential transmission line 100. Attenuation may involve reducing the amplitude of the common mode signals.

The common mode signals pass through the resistive layer 150 at an average angle significantly less than perpendicular. The odd mode (differential signals) pass through the resistive layer 150 at an average angle close to perpendicular.

In FIG. 1, the resistive layer 150 is placed between conductive structures 112, 114 in such a manner so as to be substantially perpendicular to the differential mode fields but within and substantially parallel to the common mode fields. To be very clear from the start, substantially perpendicular is not necessarily reciprocal to substantially parallel for the purposes of the differential transmission lines described herein. In this regard, substantially perpendicular is closer, on average, to being literally true for differential (first, odd) mode fields than substantially parallel is to being literally true for common (second, even) mode signals, due to the electromagnetic characteristics of these modes and signal components. Therefore, substantially perpendicular differential (first, odd) mode fields may be, on average, less than 5 degrees off from true perpendicularity to a resistive sheet 150, whereas substantially parallel common (second, even) modes fields may be, on average, close to 45 degrees off of being truly parallel to a resistive sheet 150.

The differential transmission lines described herein are built so as to have minimal loss of the fields of interest, i.e., differential (first, odd) mode fields. This minimal loss is accomplished by ensuring that the fields of interest of the differential (first, odd) mode fields are as perpendicular as possible, with a primary or median field component within 10 or even 5 degrees of true perpendicularity. On the other hand, the differential transmission lines described herein are built so as to cause maximum loss of unwanted modes such as common (second, even) mode fields. This maximum loss is accomplished better over longer distances, all other considerations being equal. Nevertheless, even a near-perpendicular common (second, even) mode field will still have vector components that are parallel to the resistive sheet 150 so as to be attenuated, especially over longer differential transmission lines.

Therefore, the term substantially parallel may be taken to mean that a median field component of a common (second, even) mode signal is, for example, as much as 45 degrees from being truly parallel to a resistive sheet. On the other hand, the term substantially perpendicular may be taken to mean that a median field component of a differential (first, odd) mode signal is no more than, for example, 10 degrees from being truly perpendicular to a resistive sheet.

The resistive layer 150 thus absorbs and diminishes the common mode signals insofar as such common mode signals include components with field lines parallel to the resistive layer 150. In FIG. 1, the resistive layer 150 is designed and placed specifically in a manner to attenuate the common mode signal components without substantially attenuating the differential mode signal components.

The sheet resistance, rather than the thickness or resistivity, of the resistive layer 150 controls the attenuation of the even or common mode signals due to the fact that the common mode electric fields are predominantly tangential to these resistive layers 150. Sheet resistance is inversely proportional to thickness for a given material. The thickness of the resistive layer 150 impacts the loss of the odd mode as the odd mode is predominantly perpendicular to the resistive layer 150. The signal attenuation is proportional to the work done by the field. For fields that are perpendicular to thin resistive layers 150, little or no work is done, and minimal signal attenuation should be observed. As long as the resistivity is sufficiently high to not look like a metal, the fields will pass through the material. For fields tangential to the resistive layer 150, for a given resistivity (material dependent), the thicker the material, the lower the sheet resistance. In both cases, there is an optimum sheet resistance. If the sheet resistance is too low, the resistive layer 150 acts like a metal, blocking the penetration of the fields. If the sheet resistance is too high, the resistive layer 150 has less of an impact. Field components will typically be attenuated least when arriving at the resistive layer 150 at a perpendicular angle, since the path through the resistive layer 150 will traverse the least possible volume of the resistive layer 150 at the perpendicular angle. As a result, a thin resistive layer 150 attenuates mostly common mode signals for fields that are not perpendicular to the resistive layer 150, whereas the thicker resistive layer 150 attenuates more common mode signals. In any event, the thin resistive layer 150 is not intended to attenuate differential mode signals, and any such attenuation is inconsequential when using the teachings of the present disclosure.

As noted above, the terms “substantially perpendicular” and “substantially parallel” may be used herein to describe the relationship between differential mode signals or common mode signals and resistive layers such as resistive layer 150, but are not to be interpreted as absolutely reciprocal terms. With respect to common mode signals, substantially parallel may mean that some field lines of the common mode signals pass through the resistive layer at tangential or near-tangential angles such that these field lines intersect the resistive layer more than would be true if they were to pass through the resistive layers at a perpendicular angle. With respect to differential mode signals, substantially perpendicular means that the field lines of the differential mode signals pass through the resistive layer at or close to 90 degree angles, such as within 5 or 10 degrees on average, such that the field lines intersect the resistive layer at or close to the minimum possible while still passing through.

The terms substantially parallel or substantially perpendicular may also apply to a group of field lines for a common mode signal or differential mode signal. Thus, when a common mode signal is referenced as intersecting (passing through) a resistive layer at a substantially parallel angle, this may be taken to mean that the majority of individual field lines of the common mode signal pass through the resistive layer at angles of 45 degrees or less. Similarly, when a differential mode signal is referenced as intersecting a resistive layer at a substantially perpendicular angle, this may be taken to mean that the majority of individual field lines of the differential mode signal pass through the resistive layer at angles of 80-100 degrees or even 85-95 degrees. To be sure, given the nature of the conductors described herein, substantially perpendicular when used with respect to differential mode signals is likely to be more strictly true than substantially parallel when used with respect to common mode signals. That is, a substantially perpendicular differential mode signal may have field lines with an average angle of 80 degrees or more relative to a resistive layer (compared to 90 degrees for an absolutely perpendicular angle), whereas a common mode signal may have field lines with an average angle of just under 45 degrees relative to a resistive layer (compared to 0 degrees for an absolutely parallel angle).

In the present disclosure, the resistive layer 150 may be made as thin as possible for a variety of reasons, even if this reduces attenuation for common mode signals, such as in fields perpendicular to the resistive layer 150. The resistive layer 150 may have a characteristic sheet resistance of approximately 100 Ohms/square, within a range of approximately 50 Ohms/square and 150 Ohms/square. The resistivity of the resistive layer is selected so as to maintain propagation of the electric field components of the differential mode of the three-dimensional electromagnetic field formed (in part) by the conductive structures 112, 114. The resistive layer 150 may also be located so as to maintain capacitance of the differential transmission line 100.

In representative embodiments, the resistive layer 150 may be continuous and extend along the direction of propagation of the differential transmission line 100 in FIG. 1. The continuity of the resistive layer is useful only inasmuch as such continuity contributes to attenuating the common mode signal components that accompany the differential transmission line 100. As such, the resistive layer 150 may also be discontinuous in the direction of propagation, so long as the lack of continuity does not substantially reduce the attenuation of the common mode signal components. A discontinuous resistive layer 150 may help maintain capacitance of the differential transmission line 100.

The differential transmission line 100 in FIG. 1 may have an outline of any appropriate shape, including a circle, ellipse, rectangle, square, or other shape. A differential transmission line 100 as in FIG. 1 or other Figures herein may also include other elements such as dielectrics as described above.

Examples of resistive layers 150 as described herein include coatings on dielectric materials. For example, a thin resistive layer may include materials such as TaN, WSiN, resistively-loaded polyimide, graphite, graphene, nickel phosphide (NiP), transition metal dichalcogenide (TMDC), nichrome (NiCr), nickel phosphorus (NiP), indium oxide, and tin oxide. The resistor materials may also be standard resistor materials such as titanium nitride (TiN) or titanium tungsten (TiW).

Transition metal dichalcogenides (TMDCs) include: HfSe2, HfS2, SnS2, ZrS2, MoS2, MoSe2, MoTe2, WS2, WSe2, WTe2, ReS2, ReSe2, SnSe2, SnTe2, TaS2, TaSe2, MoSSe, WSSe, MoWS2, MoWSe2, PbSnS2. The chalcogen family includes the Group VI elements S, Se and Te. A resistive layer 150 may have an electrical sheet resistance between 20-2500 Ohms/square and preferably between 50-150 Ohms/square.

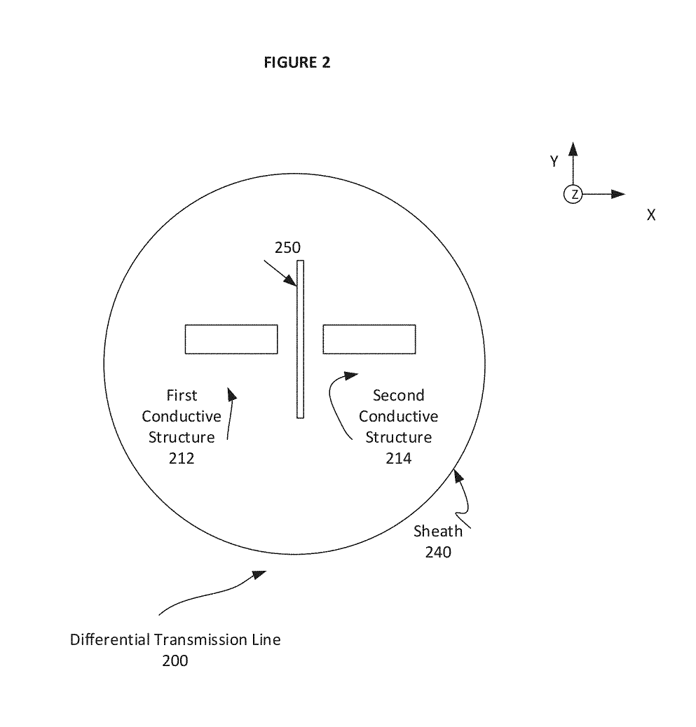

FIG. 2 shows an exemplary interior cross section of another differential transmission line 200 with common mode suppression, according to an aspect of the present disclosure. In FIG. 2, the conductive structures 212, 214 have rectangular cross sections rather than the circular cross sections of the conductive structures 112, 114 in FIG. 1. A flat, or wider conductor was previously proposed for use in coaxial cables in order to tailor impedance without introducing significant added loss, and the ability to reduce sensitivity of key parameters within manufacturing tolerances. In the previous instance, as the center conductor of a coaxial cable is made wider, the distance to the outer conductor has to increase even more than the increase in conductor width in order to maintain the same characteristic impedance. This was problematic for the proposed coaxial cables since it led to lower frequency limits, which are counterproductive for modern transmission lines used in broadband communications. However, using the differential transmission lines 200 as described herein, the benefit of flat conductive structures 212, 214 in terms of reducing loss in such differential transmission lines 200 is maintained using the resistive layers 250. That is, the onset of even mode (common) and higher order modes can be mitigated using the resistive layers 250 in the manner described herein in order to reduce the even mode (common) and higher order modes.

The view shown in FIG. 2 includes the outer sheath 240, first conductive structure 212, second conductive structure 214, and the resistive layer 250 bisecting the conductive structures 212, 214. As shown, the conductive structures 212, 214 are substantially symmetric about a center axis of the differential transmission line 200.

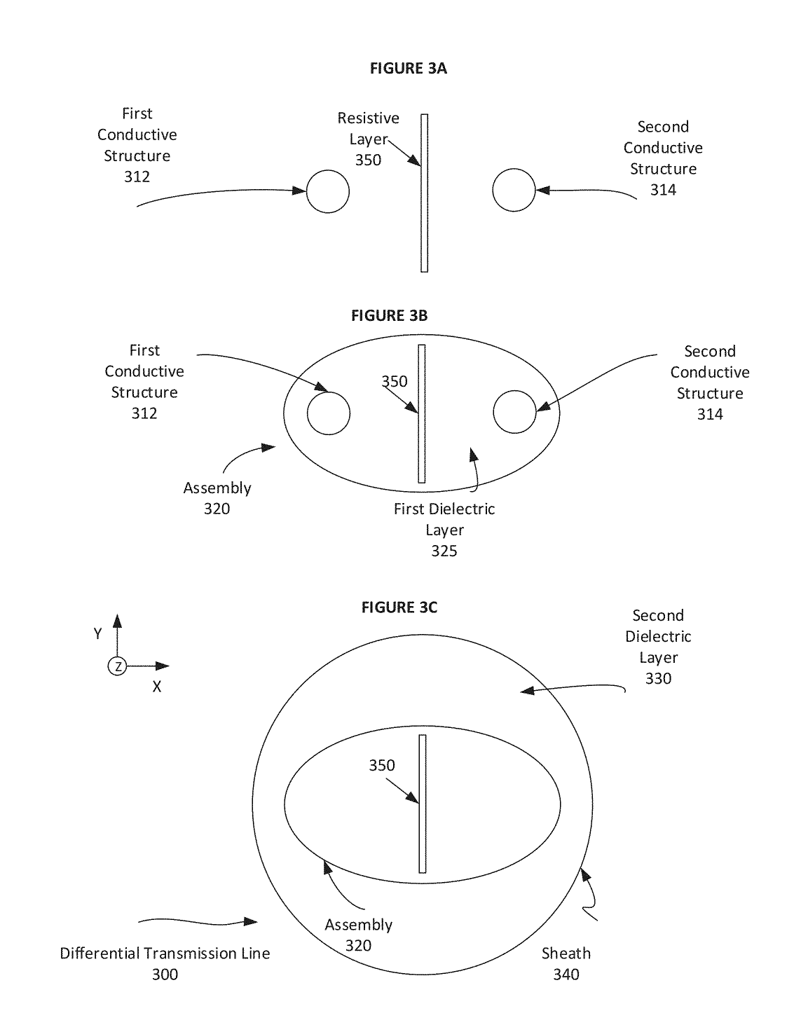

FIGS. 3A-3C show exemplary interior cross sections for another differential transmission line 300 in an assembly progression, according to an aspect of the present disclosure. In FIG. 3A, a first conductive structure 312 and second conductive structure 314 both have circular cross sections, and are arranged symmetrically on either side of resistive layer 350. Resistive layer 350 may be a resistive layer with a rectangular cross section. In FIG. 3B, the first conductive structure 312 and second conductive structure 314 are assembled in an assembly 320 with the resistive layer 350 using a first dielectric layer 325. In FIG. 3C, the assembly 320 with all interior components is assembled within the outer sheath 340 of the differential transmission line 300 using a second dielectric layer 330. Therefore, in FIGS. 3A-3C, the components of a differential transmission line 300 can be systematically assembled in, for example, a factory, using equipment that arranges the components in place as they are molded or otherwise assembled.

In FIG. 3, the electric fields of the differential signal are substantially perpendicular to the resistive layer 350 when they intersect the resistive layer 350. The electric fields of the common mode signals intersect the resistive layer 350 more extensively, and substantially less perpendicularly than the electric fields of the differential mode signals. As a result, the attenuation of the common mode signals by the resistive layer 350 is much more significant than any unintended attenuation of the differential mode signals.

As an example of a way a resistive layer 350 can be placed between the conductive structures 312, 314 for a cable, conductive structures 312, 314 are metal assemblies of finite thickness. A resistive layer 350 can be sandwiched between two metal wires as conductive structures 312, 314. Such metal wires as conductive structures 312,314 could have a flat surface (in the molding of the sleeve), and the resistive layer 350 could also be painted on the flat surfaces prior to putting the two wires together in a cable.

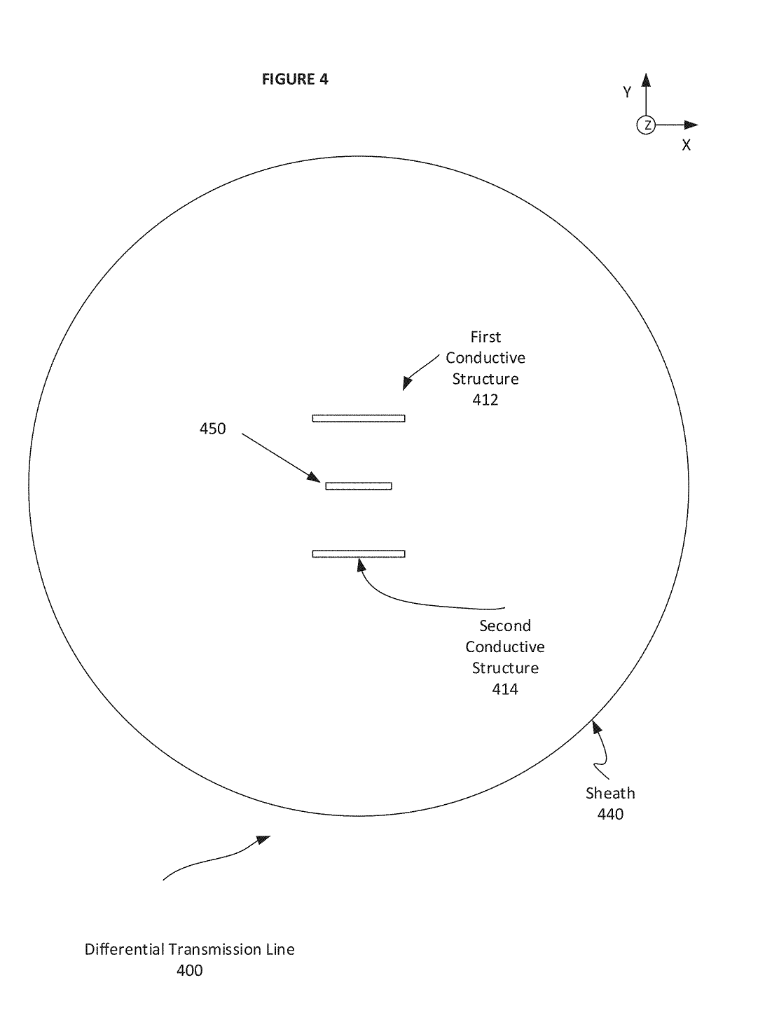

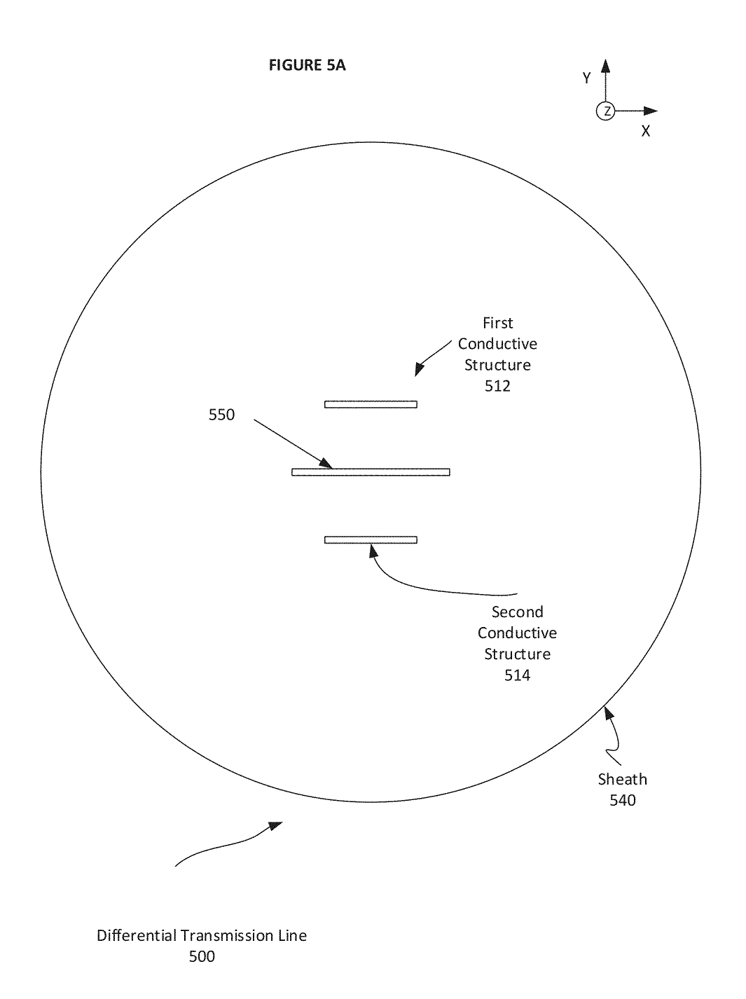

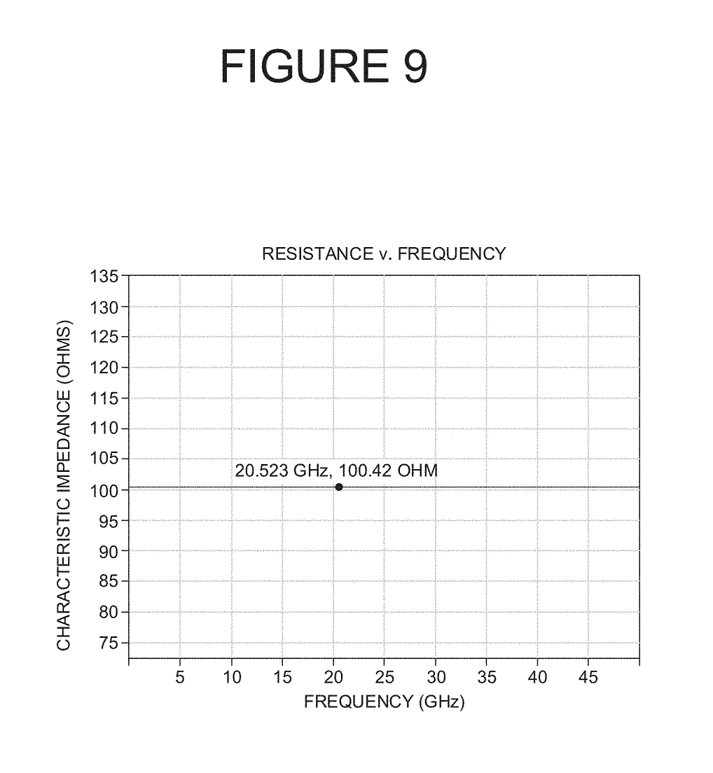

FIG. 4 shows an exemplary interior cross section of another differential transmission line 400 with common mode suppression, according to an aspect of the present disclosure. In FIG. 4, a resistive layer 450 is narrower than first conductive structure 412 and second conductive structure 414, and all three of these components are arranged with rectangular cross sections having flat tops and bottoms in the cross-sectional view. An outer sheath 440 forms the outer perimeter of the differential transmission line 400. Characteristics of the narrower resistive layer 450 are explained below in context with respect to FIGS. 9-20

FIG. 5A shows an exemplary interior cross section of another differential transmission line 500 with common mode suppression, according to an aspect of the present disclosure. In FIG. 5A, a resistive layer 550 is wider than first conductive structure 512 and second conductive structure 514, and all three of these components are again arranged with rectangular cross sections having flat tops and bottoms in the cross-sectional view. An outer sheath 540 forms the outer perimeter of the differential transmission line 500. Characteristics of the wider resistive layer 550 are explained below in context with respect to FIGS. 9-20.

FIG. 5B also shows an exemplary interior cross section of the differential transmission line 500 of FIG. 5A. In FIG. 5B, additional resistive layers 551, 552 are added in order to attenuate the second higher order mode resulting from signals along the conductive structures 512, 514. This is explained below in context with respect to FIGS. 9-20.

In FIGS. 5A and 5B, each of the conductive structures 512, 514, and the resistive layer 550 may be considered to have six significant sides including a top and bottom, a left side and right side, the front side (shown) and a rear side. In FIGS. 5A and 5B, the two largest sides of each of the conductive structures 512, 514, and the resistive layer 550, are the tops and bottoms. As noted, the conductive structures 512, 514 may be symmetric about an axis of the differential transmission line 500, for example, to make constructions simpler.

FIG. 6 shows an exemplary interior profile of a differential transmission line 600 with common mode suppression, according to an aspect of the present disclosure. In FIG. 6, the outer sheath 640 is the outermost layer of the differential transmission line 600. The resistive layer 650 is the innermost layer of the differential transmission line 600, and the conductive structure 614 is the second layer from the top and the conductive structure 612 is the second layer from the bottom. The view of FIG. 6 shows a condensed profile of, for example, a length of cable comprising the differential transmission line 600.

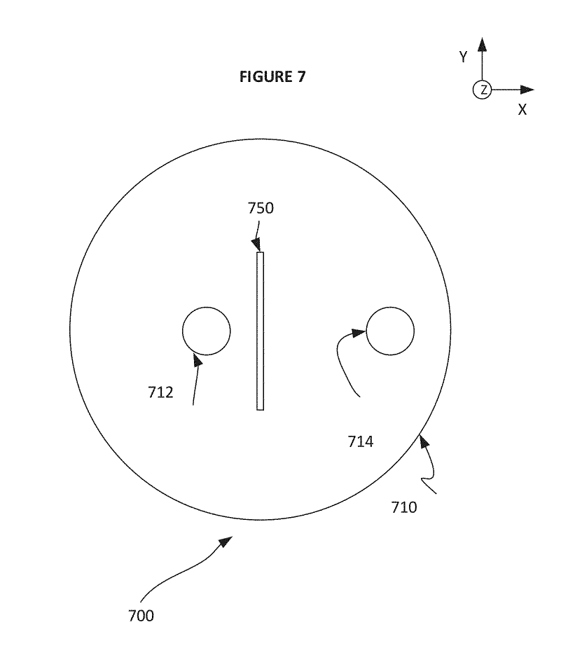

FIG. 7 shows an exemplary interior cross section of another differential transmission line 700 with common mode suppression, according to an aspect of the present disclosure. In FIG. 7, two conductive structures 712, 714 are circular in cross-sectional views, and are disposed asymmetrically about the resistive layer 750 within the outer sheath 710 of the differential transmission line 700. In FIG. 7, the conductive structures 712, 714 are similar or identical in shape and size, and are only dissimilar in that they are not arranged symmetric about the axis of the differential transmission line 700.

In FIG. 7, the resistive layer 750 is placed between the conductive structures 712, 714, and is applied to a common mode signal in the differential transmission line 700. The common mode signals in FIG. 7 would be similar to the common mode signals in FIGS. 1 and 3, and intersect the resistive layer 750 much more than differential mode signals. As an example, a resistive layer 750 may be a flat resistive layer placed on a thin dielectric and below another dielectric. The resistive layer 750 thus absorbs and diminishes the common mode signals.

In the present disclosure, the resistive layer 750 may be made as thin as possible for a variety of reasons, even if this reduces attenuation for common mode signals. The resistive layer 750 has a characteristic sheet resistance of approximately 100 Ohms/square, within a range of approximately 50 Ohms/square and 150 Ohms/square. The resistivity of the resistive layer is selected so as to maintain propagation of the electric field components of the differential mode of the three-dimensional electromagnetic field formed (in part) by the conductive structures 712, 714. The resistive layer 750 may also be located so as to maintain capacitance of the differential transmission line 700.

In an example, the differential transmission lines (e.g., 100, 700) described herein can be used in an apparatus such as a computer system with a processor and memory. For example, a differential transmission line 100, 700 can be used to connect a microprocessor to a memory. A computer system that includes the differential transmission lines (e.g., 100, 700) described herein may be a standalone device or may be connected, for example, using a network, to other computer systems or peripheral devices. Such a computer system can be implemented as or incorporated into various devices, such as a stationary computer, a mobile computer, a personal computer (PC), a laptop computer, a tablet computer, a wireless smart phone, a set-top box (STB), a personal digital assistant (PDA), a global positioning satellite (GPS) device, a communications device, a control system, a camera, a web appliance, a network router, switch or bridge, or any other machine.

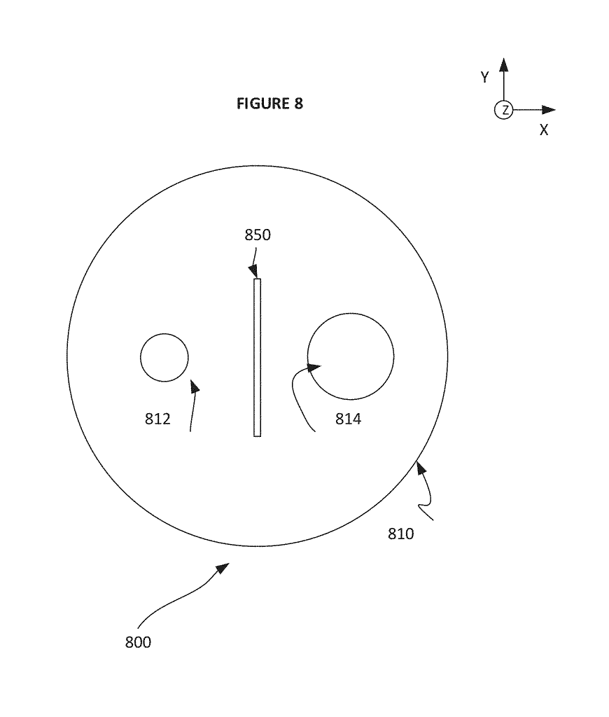

FIG. 8 shows an exemplary interior cross section of another differential transmission line 800 with common mode suppression, according to an aspect of the present disclosure. In FIG. 8, the conductive structures 812, 814 are both round, but of dissimilar sizes. They also may be symmetric or asymmetric about an axis of differential transmission line 800. The conductive structures 812, 814 are placed on different sides of the resistive layer 850, and all components are within the outer sheath 810 of the differential transmission line 800.

As in other embodiments herein, the resistive layer 850 may be broken up into segments in order to maintain capacitance of the differential transmission line 800. Such segments can be spaced apart in order to maintain capacitance of the differential transmission line 800 while still intersecting as much as possible with even mode (common) field lines. That is, such a broken up resistive layer 850 would still attenuate common mode signal components, but the spacing between such segments allows the overall assembly to better maintain capacitance. The number of such resistive layer segments, and the relative spacing between two or more such resistive layers may vary.

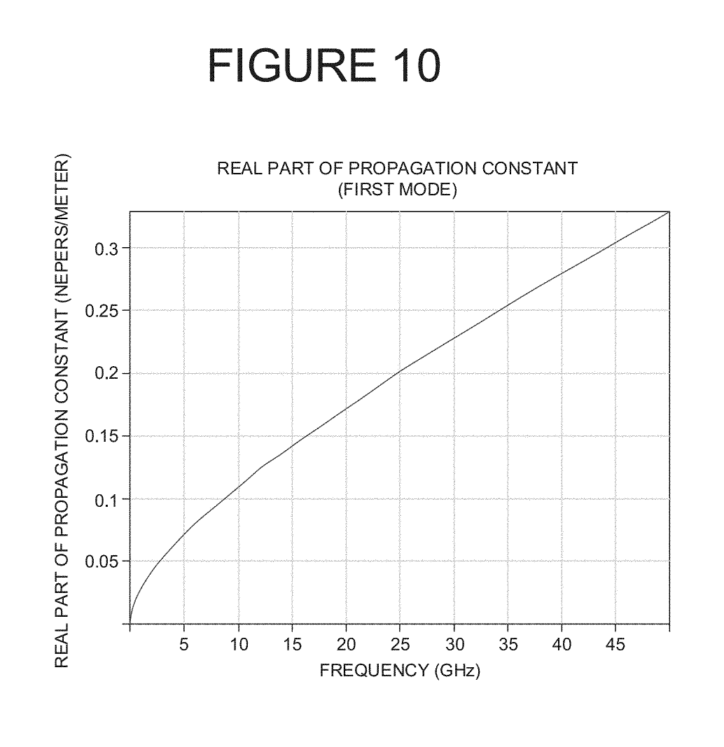

FIGS. 9-13 show charts for a differential transmission line (e.g., 400) such as the one shown in FIG. 4, but without the actual resistive layer being provided between the conductive structures 412, 414. Rather, in FIG. 9, 100 Ohm characteristic impedance for such a differential transmission line 400 is computed the same for all frequencies through 50 Gigahertz. FIGS. 10-13 show the characteristic Nepers/Meter versus frequency for the first four modes of such a differential transmission line 400.

In FIG. 9, the 100 Ohm resistance is the characteristic mode impedance between two center conductive structures 412, 414. For the characteristics described below with respect to FIGS. 9-13 using the differential transmission line 400 of FIG. 4, the differential transmission line 400 has the two conductive structures 412, 414, but not the resistive layer 450. The conductive structures 412, 414 are each 2 mm wide with 0.133 radius ends for a total width of 2.266 um. The conductive structures 412, 414 are separated by 1.4944 mm, and the minimum distance from the conductive structures 412, 414 to the outer sheath 440 is 7.62 mm. The simulated differential mode impedance shown in FIG. 9 is plotted out to 50 GHz. Also, the corresponding even-mode (common) impedance is 76.8 Ohms (Ω) measured from central lines to the outer sheath/sheath 440.

FIGS. 10-16 are described below. The plots shown in FIGS. 10-16 are of a real part of a propagation constant in Nepers/Meter versus frequency. A computer-based simulation was run to generate the plots shown in FIGS. 10-16.

FIG. 10 is a plot of Nepers/Meter versus frequency for the real part of the propagation constant for the odd-mode of the same differential transmission line 400 with common mode suppression as in FIG. 4, according to an aspect of the present disclosure. In FIG. 10, the real part of the propagation constant is plotted for the odd-mode (differential mode) of the same differential transmission line 400 as in FIG. 9 (i.e., without the resistive layer 450). An example of the readings in FIG. 10 is 0.3 Nepers/Meter at 45 Gigahertz.

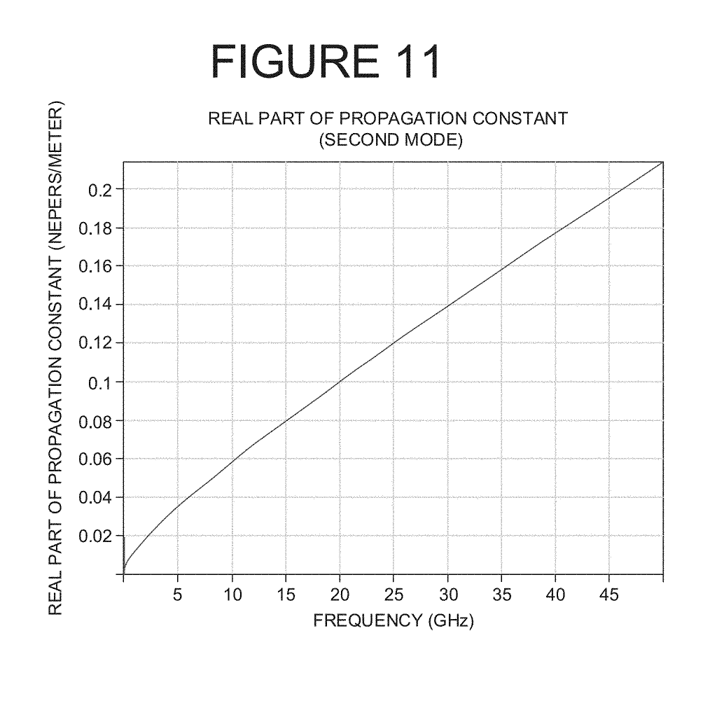

FIG. 11 is a plot of Nepers/Meter versus frequency for the real part of the propagation constant for the even-mode of the same differential transmission line 400 as in FIG. 10 (i.e., without the resistive layer 450), according to an aspect of the present disclosure. In FIG. 11, the real part of the propagation constant is plotted for the even mode (common mode) of the same differential transmission line 400 as in FIG. 9 (i.e., without the resistive layer 450). An example of the readings in FIG. 11 is 0.19 Nepers/Meter at 45 Gigahertz.

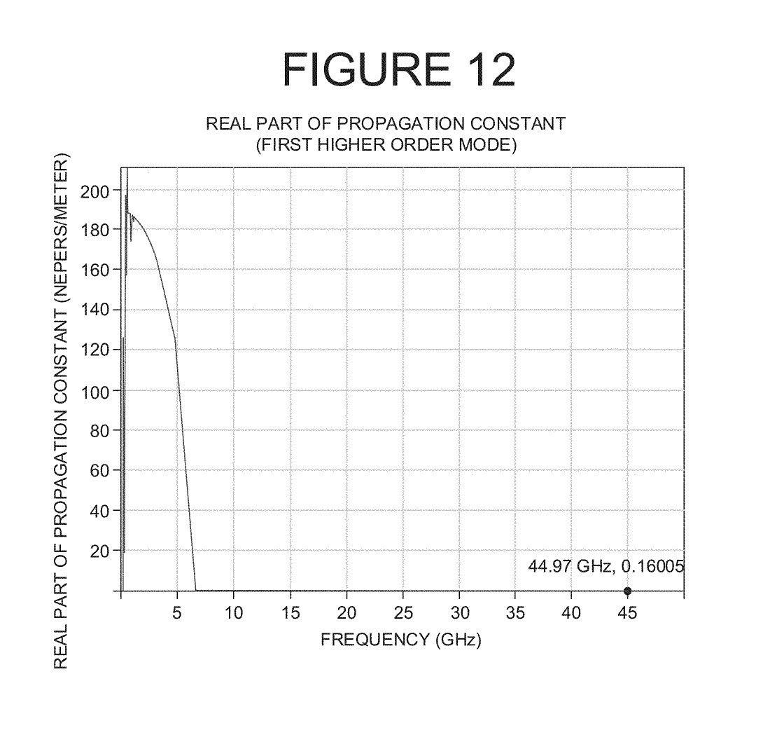

FIG. 12 is a plot of Nepers/Meter versus frequency for the real part of the propagation constant for the first higher order mode of the same differential transmission line 400 as in FIG. 10 (i.e., without the resistive layer 450), according to an aspect of the present disclosure. In FIG. 12, the real part of the propagation constant is plotted for the first higher order mode of the same differential transmission line as in FIG. 9 (i.e., without the resistive layer 450). An example of the readings in FIG. 12 is 0.16 Nepers/Meter above 6 Gigahertz.

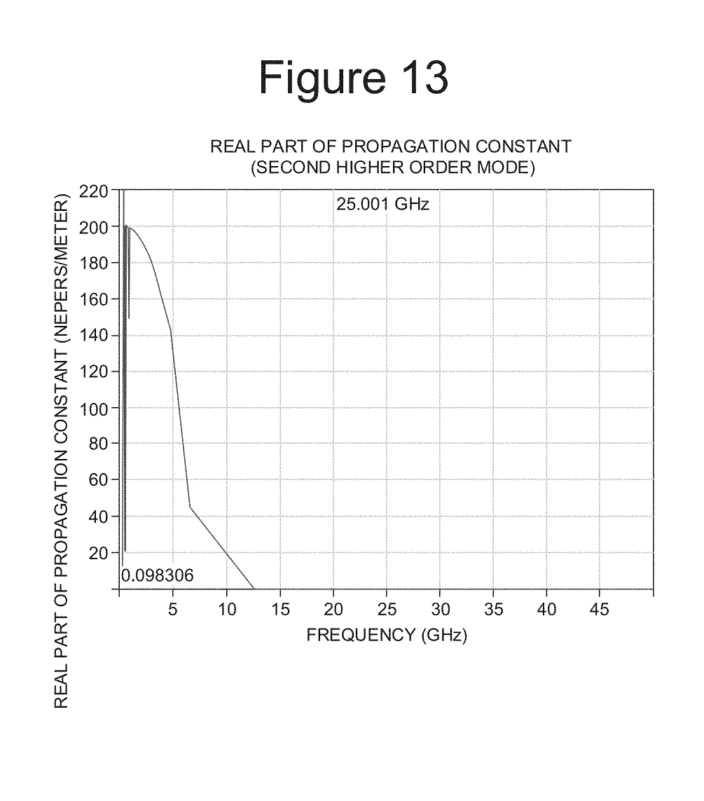

FIG. 13 is a plot of Nepers/Meter versus frequency for the real part of the propagation constant for the second higher order mode of the same differential transmission line 400 as in FIG. 10 (i.e., without the resistive layer 450), according to an aspect of the present disclosure. In FIG. 13, the real part of the propagation constant is plotted for the second higher order mode for the same differential transmission line (i.e., without the resistive layer 450), as in FIG. 9. An example of the readings in FIG. 13 is 0.098 Nepers/Meter above 13 Gigahertz.

The differential transmission line 400 shown in FIG. 4 has a relatively large diameter at the outer sheath 440 (shield). The relatively-large diameter of the outer sheath 440 supports higher order waveguide modes at lower frequencies, which is a penalty of using wider electrical conductors to reduce loss.

If, however, a thin (e.g., 6 um) resistive layer 450 is provided, a comparison can be made with the simulation results shown in FIGS. 10-13. In FIG. 4, the resistive layer 450 is narrower than the conductive structures 412, 414. If such a resistive layer 450 that is narrower than the conductive structures 412, 414 is used and has sheet resistivity of 100 Ohms/square, the primary odd (differential) mode exhibits only a slightly higher loss between 0.31 and 0.32 Nepers/Meter. This compares to 0.30 Nepers/Meter shown as the characteristic in FIG. 10 without an actual resistive layer 450 being provided. Further, as the thickness of the resistive layer is reduced, the loss for the primary odd (differential) mode approaches that of the simulation in FIG. 10 without the resistive layer. Using the same thin (e.g., 6 um) and narrow resistive layer 450 (narrower than the conductive structures 412, 414), the loss of the even mode (common) increases from 0.19 Nepers/Meter (with no resistive layer 450) shown as the characteristic in FIG. 11.

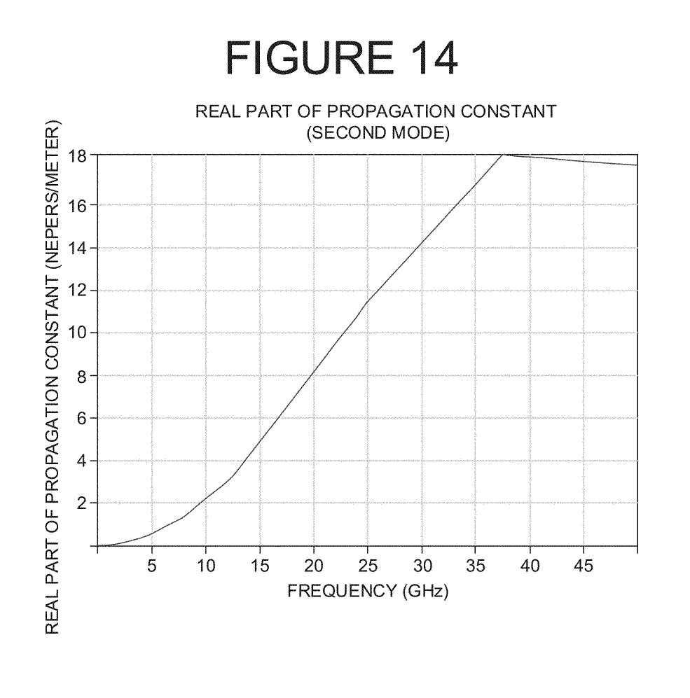

In the examples above for the characteristics shown in FIGS. 11-14 with no resistive layer 450, and in the paragraphs above with the comparison using a narrow resistive layer 450, the resistive layer 450 is relatively narrower than the conductive structures 412, 414 shown in FIG. 4. However, if a wider thin resistive layer 550 is used as in FIG. 5A such as a resistive layer 550 that is 4 mm wide, the suppression of the common mode increases dramatically (see FIG. 14), while the loss for the odd mode (differential) does not increase substantially.

FIG. 14 is a plot of Nepers/Meter versus frequency for the real part of the propagation constant for the even mode (common) of another (modified) differential transmission line 500 with common mode suppression, according to an aspect of the present disclosure. In FIG. 14, the plot of losses for the even mode (common) using the wider resistive layer 550 are shown. At 45 Gigahertz, the losses for the even mode (common) increase from 0.19 Nepers/Meter (with no resistive layer 450), 0.4 Nepers/Meter (with narrow resistive layer 450) to 18 Nepers/Meter (with 4 mm wide resistive layer 550 of FIG. 5A).

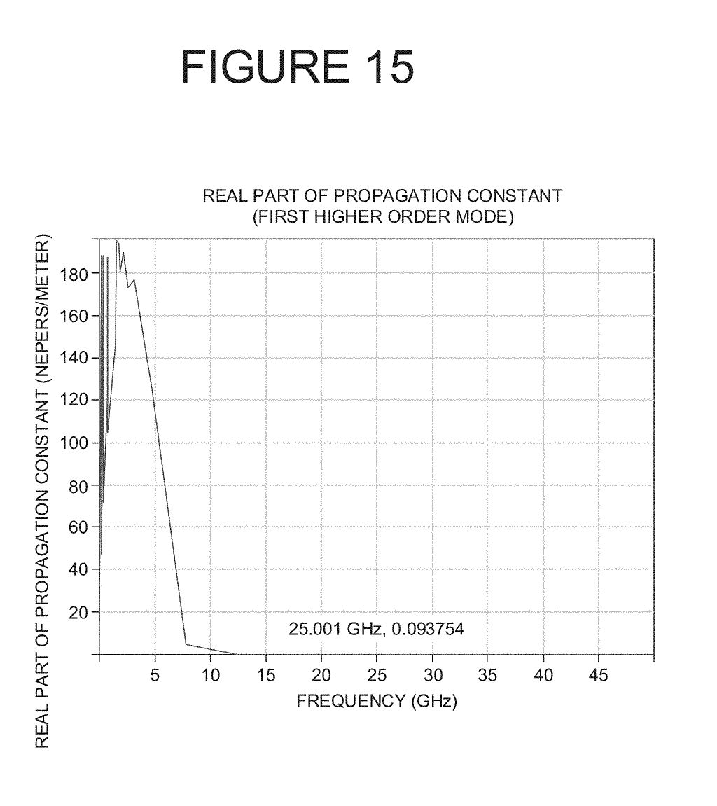

FIG. 15 is a plot of Nepers/Meter versus frequency for the real part of the propagation constant for the first higher order mode of the same modified differential transmission line 500 with common mode suppression as in FIG. 14, according to an aspect of the present disclosure. In FIG. 15, there is no significant improvement for losses in the first higher order mode, as shown by the negligible values beyond approximately 12.5 Gigahertz.

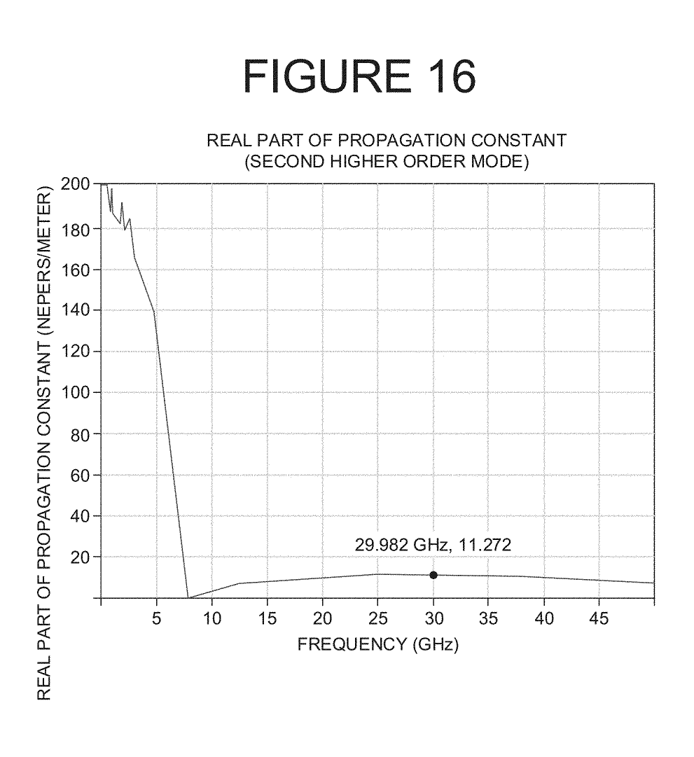

FIG. 16 is a plot of Nepers/Meter versus frequency for the real part of the propagation constant for the second higher order mode of the same modified differential transmission line 500 with common mode suppression as in FIG. 14, according to an aspect of the present disclosure. In FIG. 16, a significant improvement is shown with a value of 11.272 at ˜30 Gigahertz. This is an improvement from the reading in FIG. 13 of 0.098 Nepers/Meter above 13 Gigahertz when no resistive layer 450 is used.

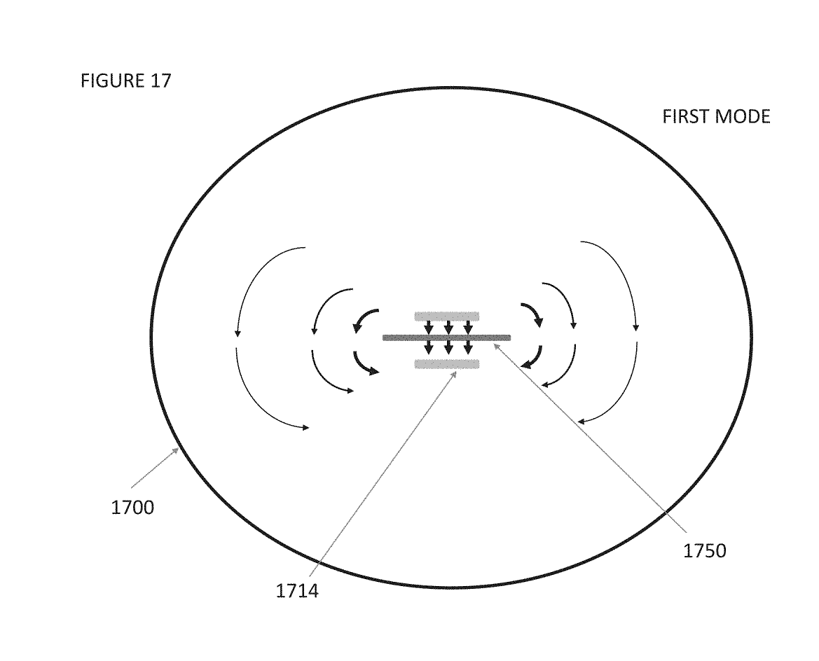

FIG. 17 shows a cross-sectional view of a differential transmission line 1700 with field lines for the odd mode, according to an aspect of the present disclosure. In FIG. 17, odd mode (differential) field lines are shown for the differential transmission line 1700. In FIG. 17, field lines all move away from the top conductive structure 1712, and towards the bottom conductive structure 1714, even when they initially emanate up from the top of the top conductive structure 1712. As shown, some field lines pass through the resistive layer 1750 at substantially perpendicular angles.

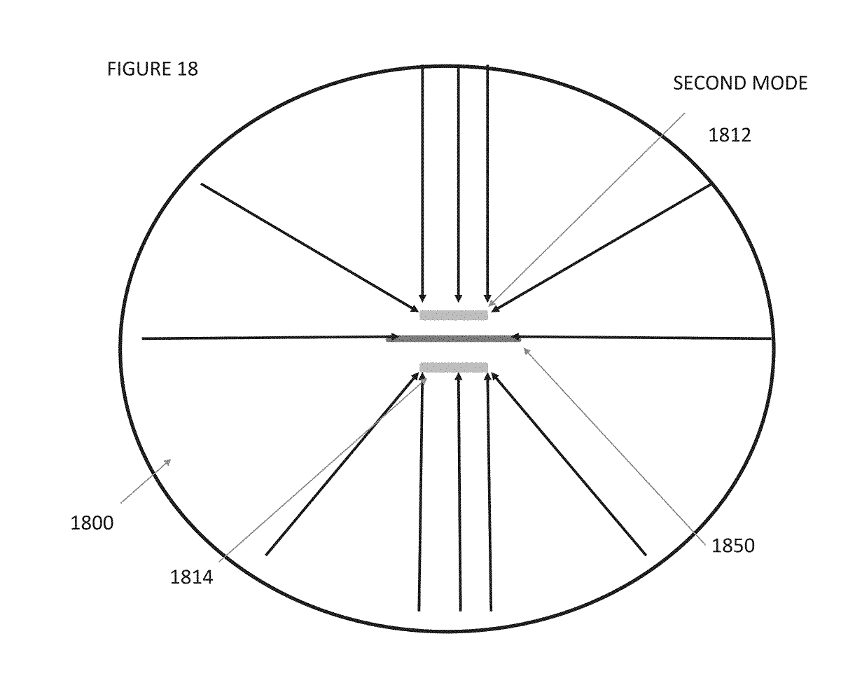

FIG. 18 shows a cross-sectional view of the same differential transmission line 1700 as in FIG. 17 but labeled 1800 and with field lines for the even mode, according to an aspect of the present disclosure. In FIG. 18, even mode (common) field lines are shown for the differential transmission line 1800. In FIG. 18, even mode (common) field lines are pulled towards each of the top conductive structure 1812 and bottom conductive structure 1814. Field components of the even mode (common) are drawn substantially parallel to the resistive layer 1850 in FIG. 18, and are therefore subject to greater attenuation than the field components for the odd mode in FIG. 17 (which intersect the resistive layer 1750 at substantially perpendicular angles).

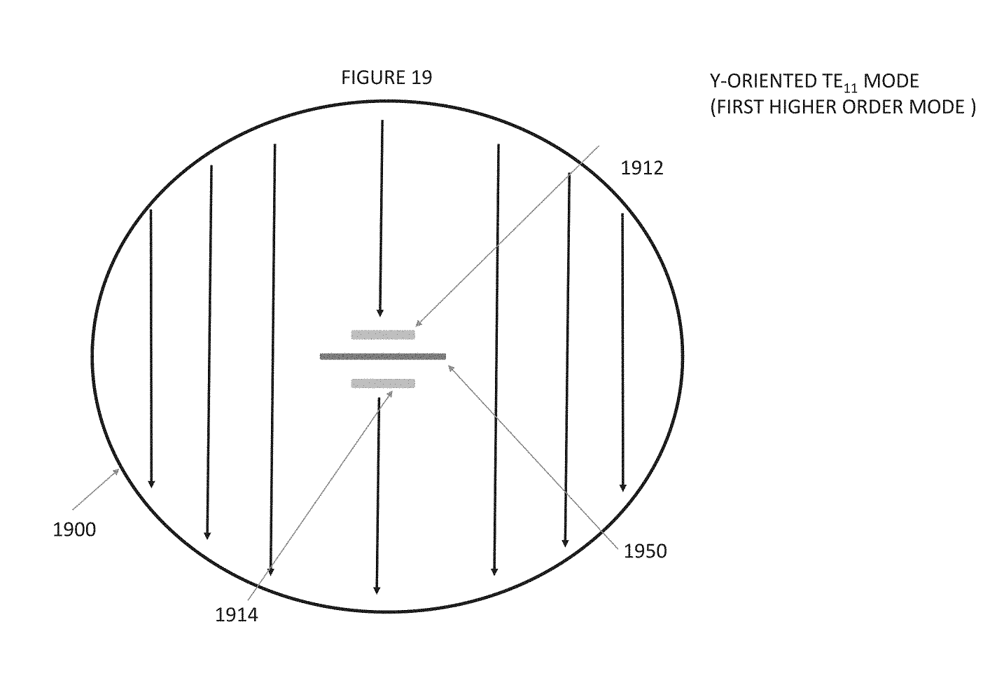

FIG. 19 shows a cross-sectional view of the same differential transmission line 1700 as in FIG. 17 but labeled 1900 and with field lines for the first higher order mode, according to an aspect of the present disclosure. In FIG. 19, field components of the first higher order mode mostly pass through the resistive layer 1950 at substantially perpendicular angles. Therefore, the first higher order mode is not subject to large losses using the wider resistive layer 1950.

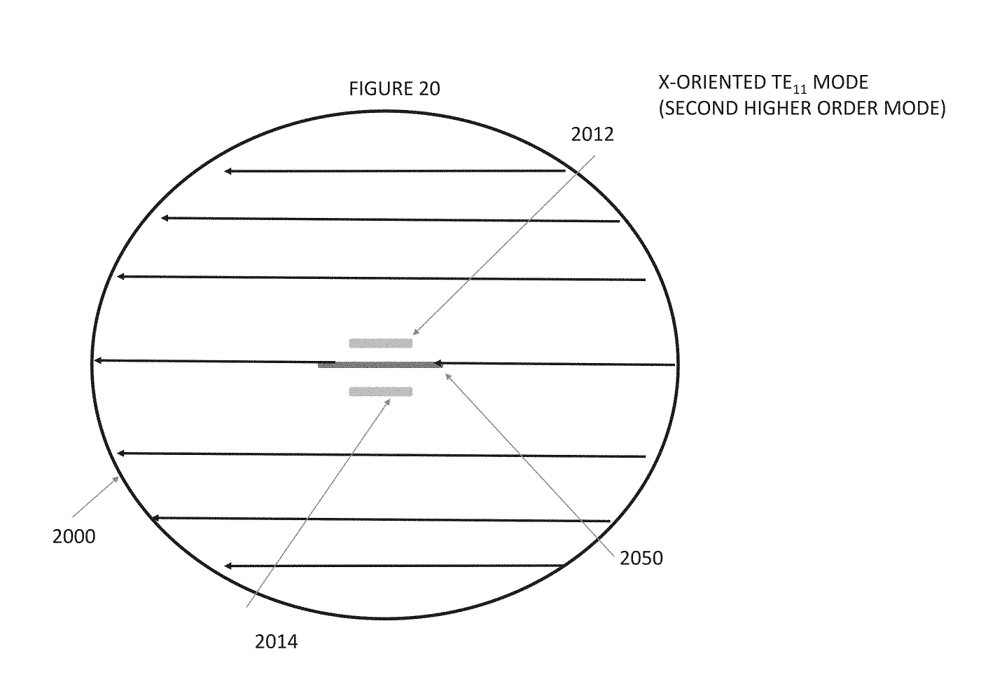

FIG. 20 shows a cross-sectional view of the same differential transmission line 1700 as in FIG. 17 but labeled as 2000 and with field lines for the second higher order mode, according to an aspect of the present disclosure. In FIG. 20, some field components of the second higher order mode pass through the resistive layer 2050 at substantially parallel angles. Therefore, the second higher order mode is subject to significant attenuation using the wider resistive layer 2050.

From the electric field plots in FIGS. 17-20, one can see that even adding a thin resistive layer 1950 between the conductive structures 1912, 1914 does not significantly impact the odd mode or the first higher order mode (i.e., the 3rd or X-oriented mode). This is because the electric fields for the odd mode and the first higher order mode are substantially perpendicular to the thin resistive layer 1950. The even mode and the second higher order mode (i.e., the 4th or Y-oriented mode) have electric field components that are more tangential (parallel) to the sheet, and are therefore subject to more substantial attenuation.

To achieve better attenuation for the differential transmission lines with the wider resistive layers (e.g., 550, 1950), in FIG. 5B additional thin resistive layers 551, 552 are added on the sides of the resistive layer 550 so as to be parallel to the electric field components of the first higher order mode while still being perpendicular to electric field components of the odd mode (differential). These resistive layers 551, 552 are constructed at a distance of 6.6 mm from the outer sheath 540. The resistive layers 551, 552 are formed by wrapping a thin resistive layer and then chopping it so that only left and right sides of the sheet remain. These resistive layers 551, 552 result in increased attenuation of the first higher order mode.

The losses for a differential transmission line 550 shown in FIG. 5B with resistive layers 551, 552 are as follows. There is no substantial increase in loss for the odd mode (differential). The even mode (common), experiences a loss corresponding to a propagation constant of ˜18 Nepers/Meter, which is similar to the loss for a differential transmission line 550 in FIG. 5A with only a central resistive layer 550. However, the first higher order mode (i.e., mode 3, or the X mode), exhibits a real-part of propagation constant of 1.17 Nepers/Meter, compared to 0.09 Nepers/Meter for the differential transmission line 550 in FIG. 5A with only a central resistive layer 550. The second higher order mode (i.e., mode 4, or the Y mode), exhibits a real part of propagation of ˜11 Nepers/Meter, which is about the same as the differential transmission line 550 in FIG. 5A.

As a result of the characteristics described above, the differential transmission lines 500 in FIGS. 5A and 5B can help achieve lower losses for undesirable modes. Using the wider conductive structures 512, 514 helps achieve lower loss for a differential signal. To maintain the impedance, the distance from the conductive structures 512, 514 to the outer sheath 540 is made relatively large, which dramatically lowers the onset of higher order modes. The even mode (common) and second higher order mode can be mitigated effectively using the first and second conductive structures 512, 514 along with the resistive layer 550, and the first higher order mode can be mitigated using thin resistive layers 551, 552. As a result, conversion between common and differential mode is dramatically reduced.

The present disclosure describes resistive layers applied to suppress common mode and higher order modes. This application of resistive layers is used to suppress common mode signals in a differential transmission line. As context, a cross sectional view of a differential transmission line would appear as the front face of a cable with two, e.g., horizontal or vertical metal segments aligned with a space between in which a resistive layer is placed. The signal of interest is carried by differences of voltage and current between the two metal segments. Signals that are common between these segments are of interest in the present disclosure, as these signals may be unwanted. Using resistive layers as described herein avoids complicated construction and assembly, and does not add significant bulk to a differential transmission line, and is not restricted to specific (narrow) frequency bands.

Accordingly, differential transmission line with common mode suppression enables a simple mechanism to suppress common mode signals. The differential transmission line described herein is simpler than using resonators in some or possibly all cases. That is, using the differential transmission line described herein, common mode signals can be appropriately attenuated without imposing intolerable losses on differential mode signals. In turn, the differential transmission line described herein can then provide greater bandwidth than would otherwise be possible.

Additionally, the differential transmission line described herein is broadband. This is more useful than a solution that offers common mode suppression over a narrow range of frequencies.

Moreover, the differential transmission line described herein is applicable to a wide variety of differential signal structures. The differential transmission line described herein is applicable to a variety of transmission lines with exterior profiles that may be, but do not have to be, circular.

Many applications exist for a differential transmission line in, for example, a broadband cable or local area network cable. Such applications may include
Wired local area networks (LANs), such as gigabit Ethernet. Such wired local area networks may use numerous pairs of wires to run differential signals. The “common mode” filter aspect of the present disclosure may be used on each end of the pairs of wires, or anywhere before the signals run into an analog to digital converter (ADC) before being processed by a digital signal processor (DSP) dedicated to extracting the signals.
Lines from a differential antenna to a receiver. Such lines can be adapted to include a differential transmission line as a (relatively) small circuit at one end to suppress any common mode signal.
For digital communications between parts of a computer system, such as standard PCI Express. Each “lane” of PCI Express sends “packets” down differential pairs, in a manner very similar to Ethernet (described above).

Although differential transmission line with common mode suppression has been described with reference to several exemplary embodiments, it is understood that the words that have been used are words of description and illustration, rather than words of limitation. Changes may be made within the purview of the appended claims, as presently stated and as amended, without departing from the scope and spirit of differential transmission line with common mode suppression in its aspects. Although differential transmission line with common mode suppression has been described with reference to particular means, materials and embodiments, differential transmission line with common mode suppression is not intended to be limited to the particulars disclosed; rather differential transmission line with common mode suppression extends to all functionally equivalent structures, methods, and uses such as are within the scope of the appended claims.

Although the present specification describes components and functions that may be implemented in particular embodiments with reference to particular standards and protocols, the disclosure is not limited to such standards and protocols. Such standards are periodically superseded by more efficient equivalents having essentially the same functions. Accordingly, replacement standards and protocols having the same or similar functions are considered equivalents thereof.

The illustrations of the embodiments described herein are intended to provide a general understanding of the structure of the various embodiments. The illustrations are not intended to serve as a complete description of all of the elements and features of the disclosure described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

According to an aspect of the present disclosure, a differential transmission line includes a sheath, a first conductive structure, a second conductive structure, and one or more resistive layers. The first conductive structure is disposed along the differential transmission line and within the sheath, and contributes to formation of a three-dimensional electromagnetic field. The second conductive structure is disposed along the differential transmission line and within the sheath, spaced throughout the sheath at a substantially constant distance from the first conductive structure, and contributes to formation of the three-dimensional electromagnetic field. Any resistive layer is aligned to be substantially perpendicular to an electric field component of a first mode of the three-dimensional electromagnetic field, and to be substantially parallel to an electric field component of a second mode of the three-dimensional electromagnetic field.

According to another aspect of the present disclosure, the differential transmission line comprises a cable. The first conductive structure comprises a first wire. The second conductive structure comprises a second wire.

According to yet another aspect of the present disclosure, the first conductive structure and the second conductive structure have substantially identical cross-sections.

According to still another aspect of the present disclosure, the differential transmission includes a first dielectric layer between the first conductive structure and the second conductive structure.

According to another aspect of the present disclosure, the differential transmission line includes a second dielectric layer; and an assembly that includes the first dielectric layer, the first conductive structure, and the second conductive structure. The second dielectric layer is provided between the assembly and the sheath.

According to still another aspect of the present disclosure, the first conductive structure and the second conductive structure are disposed symmetrically about an axis of the differential transmission line.

According to yet another aspect of the present disclosure, the resistive layer attenuates the second mode of the three-dimensional electromagnetic field by being substantially parallel to the electric field components of the second mode of the three-dimensional electromagnetic field so as to provide the absorption of electric field components.

According to another aspect of the present disclosure, the sheath forms a closed shape in a cross-section transverse to a direction of propagation of the differential transmission line.

According to still another aspect of the present disclosure, the first conductive structure has parallelogram sides. The second conductive structure has parallelogram sides.

According to yet another aspect of the present disclosure, the sheath comprises a grounded metal.

According to still another aspect of the present disclosure, the resistive layer is provided between the first conductive structure and the second conductive structure.

According to another aspect of the present disclosure, the first mode comprises an odd mode of the three-dimensional electromagnetic field. A resistivity of the resistive layer is selected so as to maintain propagation of field components of the odd mode of the three-dimensional electromagnetic field.

According to yet another aspect of the present disclosure, the resistive layer has a characteristic sheet resistance between approximately 50 Ohms/square and 150 Ohms/square.

According to still another aspect of the present disclosure, the resistive layer has a characteristic sheet resistance between approximately 50 and 100 Ohms/square.

According to another aspect of the present disclosure, the second mode comprises an even mode of the three-dimensional electromagnetic field. The resistive layer reduces amplitudes of the even mode.

According to yet another aspect of the present disclosure, the first conductive structure has a first flat side. The second conductive structure has a second flat side. The first flat side of the first conductive structure faces the second flat side of the second conductive structure.

According to still another aspect of the present disclosure, all sides other than the first flat side of the first conductive structure are not wider than the first flat side in a cross-sectional view.

According to another aspect of the present disclosure, all sides other than the second flat side of the second conductive structure are not wider than the second flat side in a cross-sectional view.

According to yet another aspect of the present disclosure, the first conductive structure has a third flat side opposite from the first flat side. The second conductive structure has a fourth flat side opposite from the second flat side.

According to still another aspect of the present disclosure, the first flat side, second flat side, third flat side and fourth flat side have substantially equivalent widths in a cross-sectional view of the differential transmission line. The widths of the first flat side, second flat side, third flat side and fourth flat side are smaller than a width of the resistive layer in a cross-sectional view.

According to another aspect of the present disclosure, the resistive layer is placed between the first flat side of the first conductive structure and the second flat side of the second conductive structure. The resistive layer is wider in a cross-sectional view than the first flat side of the first conductive structure and the second flat side of the second conductive structure.

According to another aspect of the present disclosure, the differential transmission line includes at least one additional resistive layer to a side of the first conductive structure, second conductive structure, and resistive layer, and within the sheath.

The Abstract of the Disclosure is provided to comply with 37 C.F.R. §1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The preceding description of the disclosed embodiments is provided to enable any person skilled in the art to make or use the present disclosure. As such, the above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A differential transmission line, comprising:
a sheath;
a first conductive structure disposed along the differential transmission line and within the sheath, and contributing to formation of a three-dimensional electromagnetic field;
a second conductive structure disposed along the differential transmission line and within the sheath, and contributing to formation of the three-dimensional electromagnetic field; and
a resistive layer aligned to be substantially perpendicular to an electric field component of a first mode of the three-dimensional electromagnetic field, and to provide absorption of electric field components of a second mode of the three-dimensional electromagnetic field.

2. The differential transmission line of claim 1,
wherein the differential transmission line comprises a cable,
wherein the first conductive structure comprises a first wire, and
wherein the second conductive structure comprises a second wire.

3. The differential transmission line of claim 1,
wherein the first conductive structure and the second conductive structure have substantially identical cross-sections.

4. The differential transmission line of claim 1, further comprising:
a first dielectric layer between the first conductive structure and the second conductive structure.

5. The differential transmission line of claim 4, further comprising:
a second dielectric layer; and
an assembly that includes the first dielectric layer, the first conductive structure, and the second conductive structure,
wherein the second dielectric layer is provided between the assembly and the sheath.

6. The differential transmission line of claim 1,
wherein the first conductive structure and the second conductive structure are disposed symmetrically about an axis of the differential transmission line.

7. The differential transmission line of claim 1,
wherein the resistive layer attenuates the second mode of the three-dimensional electromagnetic field by being substantially parallel to the electric field components of the second mode of the three-dimensional electromagnetic field so as to provide the absorption of electric field components.

8. The differential transmission line of claim 1,
wherein the sheath forms a closed shape in a cross-section transverse to a direction of propagation of the differential transmission line.

9. The differential transmission line of claim 1,
wherein the first conductive structure has parallelogram sides, and
wherein the second conductive structure has parallelogram sides.

10. The differential transmission line of claim 1,
wherein the sheath comprises a grounded metal.

11. The differential transmission line of claim 1,
wherein the resistive layer is provided between the first conductive structure and the second conductive structure.

12. The differential transmission line of claim 1,
wherein the first mode comprises an odd mode of the three-dimensional electromagnetic field, and
wherein a resistivity of the resistive layer is selected so as to maintain propagation of field components of the odd mode of the three-dimensional electromagnetic field.

13. The differential transmission line of claim 1,
wherein the resistive layer has a characteristic sheet resistance between approximately 50 Ohms/square and 150 Ohms/square.

14. The differential transmission line of claim 1,
wherein the resistive layer has a characteristic sheet resistance between approximately 50 and 100 Ohms/square.

15. The differential transmission line of claim 1,
wherein the second mode comprises an even mode of the three-dimensional electromagnetic field, and
wherein the resistive layer reduces amplitudes of the even mode.

16. The differential transmission line of claim 1,
wherein the first conductive structure has a first flat side,
wherein the second conductive structure has a second flat side, and
wherein the first flat side of the first conductive structure faces the second flat side of the second conductive structure.

17. The differential transmission line of claim 16,
wherein all sides other than the first flat side of the first conductive structure are not wider than the first flat side in a cross-sectional view, and
wherein all sides other than the second flat side of the second conductive structure are not wider than the second flat side in a cross-sectional view.

18. The differential transmission line of claim 16,
wherein the first conductive structure has a third flat side opposite from the first flat side, wherein the second conductive structure has a fourth flat side opposite from the second flat side,
wherein the first flat side, second flat side, third flat side and fourth flat side have substantially equivalent widths in a cross-sectional view of the differential transmission line, and
wherein the widths of the first flat side, second flat side, third flat side and fourth flat side are smaller than a width of the resistive layer in a cross-sectional view.

19. The differential transmission line of claim 16,
wherein the resistive layer is placed between the first flat side of the first conductive structure and the second flat side of the second conductive structure, and
wherein the resistive layer is wider in a cross-sectional view than the first flat side of the first conductive structure and the second flat side of the second conductive structure.

20. The differential transmission line of claim 1, further comprising:
at least one additional resistive layer to a side of the first conductive structure, second conductive structure, and resistive layer, and within the sheath.
